(19) United States
(12) Patent Application Publication
(10) Pub. No.: US 2008/0237778 A1
(43) Pub. Date: Oct. 2, 2008

(54) SEMICONDUCTOR DEVICE AND METHOD FOR MANUFACTURING THE SAME

(75) Inventor: Kei KANEMOTO, Suwa (JP)

Correspondence Address: HARNESS, DICKEY & PIERCE, P.L.C., P.O. BOX 828, BLOOMFIELD HILLS, MI, 48303, US

(73) Assignee: SEIKO EPSON CORPORATION, Tokyo (JP)

(21) Appl. No.: 12/053,931

(22) Filed: Mar. 24, 2008

(30) Foreign Application Priority Data
Mar. 27, 2007 (JP) 2007-081869

(51) Int. Cl. H01L 23/58; H01L 21/762

(52) U.S. Cl. 257/506; 438/404; 257/E21.564; 257/E23.002

(57) ABSTRACT

A method for manufacturing a semiconductor device having a silicon-on-insulator region and a bulk region in a same semiconductor substrate, the method includes: (a) etching the semiconductor substrate in the silicon-on-insulator region so as to form a concave; (b) forming a first semiconductor layer and subsequently a second semiconductor layer on the semiconductor substrate in the silicon-on-insulator region, so as to bury the concave; (c) etching the second semiconductor layer and the first semiconductor layer partially, so as to form a trench which exposes a side surface of the first semiconductor substrate in the silicon-on-insulator region; (d) etching the first semiconductor layer through the trench with an etching condition in which the first semiconductor layer is easier to be etched than the second semiconductor layer, so as to form a cavity between the semiconductor substrate and the second semiconductor layer in the silicon-on-insulator region; and (e) forming a buried insulating film inside the cavity.

The entire disclosure of Japanese Patent Application No. 2007-081869, filed Mar. 27, 2007 is expressly incorporated by reference herein.

### BACKGROUND

1. Technical Field

The present invention relates to a semiconductor device a method for manufacturing a semiconductor device, particularly to a technique for forming a silicon-on-insulator (SOI) structure on a semiconductor substrate.

2. Related Art

Examples thereof are disclosed in JP-A-2005-354024, JP-A-2006-108206, and T. Sakai et al. “Separation by Bonding Si Islands (SBSI) for LSI Application” Second International SiGe Technology and Device Meeting, Meeting Abstract, pp. 230-231, May 2004. Methods disclosed therein are called the SBSI method which forms an SOI structure partially on a bulk substrate. According to the SBSI method, a silicon (Si) layer and a silicon germanium (SiGe) layer are deposited on a Si substrate, and only the SiGe layer is then selectively removed by taking an advantage of a difference in the etching ratio of Si and SiGe, so as to form a cavity between the Si substrate and the Si layer. Subsequently, a top surface of the Si substrate and a bottom surface of the Si layer which are facing an interior of the cavity are thermally oxidized, so as to form a SiO₂ film (hereafter also referred to as “buried oxide (BOX) layer”) between the Si substrate and the Si layer. Thereafter, a film such as a SiO₂ film is deposited on the Si substrate with CVD method, thereafter CMP planarized and etched with solutions such as diluted hydrofluoric acid (HF), so as to expose the surface of the Si layer (hereafter also referred to as “SOI layer”) on the BOX layer.

JP-A-2006-108206 discloses a method for fabricating a bulk element and an SOI element on a same substrate using the SBSI method. This method allows the realization of system-on-chip (SOC) while suppressing the cost increase, since the substrate includes both an SOI transistor and a bulk transistor fabricated thereon, the SOI transistor operated in high-speed in low power consumption, allowing an easy low-voltage drive, and the bulk transistor having a high current drive power and a high voltage tolerance. There is an increasing demand for cost reduction and increased reliability in methods for manufacturing such highly functional semiconductor device, and the further improvements are desired, such as reducing the number of manufacturing processes and improving yields.

### SUMMARY

An advantage of the invention is to provide a method for manufacturing a semiconductor device that is produced with high efficiency, the device having a silicon-on-insulator region and a bulk region fabricated in a same semiconductor substrate. Another advantage is to provide a highly reliable semiconductor device.

According to a first aspect of the invention, a method for manufacturing a semiconductor device having a silicon-on-insulator region and a bulk region in a same semiconductor substrate, the method includes: (a) etching the semiconductor substrate in the silicon-on-insulator region so as to form a concave; (b) forming a first semiconductor layer and subsequently a second semiconductor layer on the semiconductor substrate in the silicon-on-insulator region, so as to bury the concave; (c) etching the second semiconductor layer and the first semiconductor layer partially, so as to form a trench which exposes a side surface of the first semiconductor substrate in the silicon-on-insulator region; (d) etching the first semiconductor layer through the trench with an etching condition in which the first semiconductor layer is easier to be etched than the second semiconductor layer, so as to form a cavity between the semiconductor substrate and the second semiconductor layer in the silicon-on-insulator region; and (e) forming a buried insulating film inside the cavity.

Here, the bulk region means either a region where an underlying layer thereof is composed only with a semiconductor substrate, or, a region composed only with a semiconductor substrate and with a semiconductor layer formed thereon. In the invention, an SOI structure means a structure in which a semiconductor layer is deposited on a buried insulating film, and a region in which the SOI structure is formed is referred to as an “SOI region”.

In this case, the semiconductor substrate is etched in the step (a) so that the depth of the concave becomes as large as a sum of film thicknesses of the first semiconductor layer and the second semiconductor layer.

The manufacturing method according to the first aspect of the invention decrease the difference in height between the surface of the second semiconductor layer in the SOI region and the surface of the semiconductor substrate in the bulk region. Further, in the above case where the depth of the concave becomes as large as the sum of film thicknesses of the first semiconductor layer and the second semiconductor layer, the surface of the second semiconductor layer in the SOI region and the surface of the semiconductor substrate in the bulk region are aligned to the same height, so that elements can be formed in both regions at the same height.

In the case of forming transistors as an example of the aforementioned elements, gate electrodes are formed on the second semiconductor layer in the SOI region as well as on the semiconductor substrate in the bulk region, the gate electrodes in both regions having the same height. This allows an exposure condition of the SOI region to approximately match that of the bulk region in a photolithography process during the forming of the gate electrodes, thereby simultaneously providing an optimal condition to both the SOI region and the bulk region. Consequently, it is possible to provide a method for manufacturing a semiconductor device produced with high efficiency.

Compared to the case of individually carrying out a focusing on the SOI region and on the bulk region so as to carry out the exposure process, the above method reduces the complexity of focusing, thereby shortening the processing time and the like in the exposure process. Moreover, in the case of carrying out the exposure processing on both the SOI region and the bulk region at the same time (i.e. simultaneously carrying out the exposure processing through the same lens), the focusing on both regions can be carried out at the same time, which allows the formation of gate electrodes in both regions in a high precision. Consequently, a semiconductor device is fabricated in accordance with the designed values, and therefore the semiconductor device exhibits desired performance and is high reliable.

In this case, the method for manufacturing a semiconductor device according to the first aspect of the invention further includes: (f) forming a protection film on the semiconductor substrate in the bulk region, prior to the step (b); and (g) exposing a surface of the semiconductor substrate in the silicon-on-insulator region from under the protection film; the step (b) including selective epitaxial growth of the first semiconductor layer on the surface of the semiconductor substrate exposed from under the protection film, as well as the selective epitaxial growth of the second semiconductor layer on the surface of the first semiconductor layer.

Formation of the first semiconductor layer and the second semiconductor layer over the semiconductor substrate in the bulk region is prevented with the methods described above.

In this case, the method for manufacturing a semiconductor device further includes: (h) forming a support from over the second semiconductor layer in the silicon-on-insulator region to over the semiconductor substrate in a vicinity of the silicon-on-insulator region, between the forming of the second semiconductor layer in the step (b) and the step (d); the step (d) including etching the first semiconductor layer under the second semiconductor layer, in a state the semiconductor layer in the silicon-on-insulator region being supported by the support.

This prevents the second semiconductor layer from sinking (i.e. being depressed) into the interior of the cavity, during a period after the forming of the cavity and until the completion of forming the buried insulating film.

In this case, the method further includes: forming a recess local-oxidation-of-silicon layer on the semiconductor substrate in the vicinity of the silicon-on-insulator region as an element isolation layer, prior to the step (a); the step (h) including forming the support from above the semiconductor layer in the silicon-on-insulator region to above the recess local-oxidation-of-silicon layer.

Here, the recess LOCOS layer is a layer formed by dry etching the semiconductor substrate surface exposed from under an oxidation prevention film (e.g. silicon nitride film) so as to form a concave, and subsequently carrying out LOCOS oxidation so as to bury the concave. The recess LOCOS layer is formed by oxidizing the bottom surface as well as the side surface of the concave formed within the semiconductor substrate. Therefore, compared to the common LOCOS layer, the surface height of this recess LOCOS layer is lower.

With this method, compared to the case of forming the common LOCOS layers, the surfaces of the semiconductor substrate and the element isolation layer are aligned approximately to the same height, thereby contributing to the planarization of the semiconductor device.

According to a second aspect of the invention, a method for manufacturing a semiconductor device having a silicon-on-insulator region and a bulk region in a same semiconductor substrate, the method includes: forming a first semiconductor layer on the semiconductor substrate in the silicon-on-insulator region, while not forming the first semiconductor layer on the semiconductor substrate in the bulk region; forming a second semiconductor layer on the first semiconductor layer in the silicon-on-insulator region as well as on the semiconductor substrate in the bulk region; etching the second semiconductor layer and the first semiconductor layer partially, so as to form a trench which exposes a side surface of the first semiconductor substrate in the silicon-on-insulator region; etching the first semiconductor layer through the trench with an etching condition in which the first semiconductor layer is easier to be etched than the second semiconductor layer, so as to form a cavity between the semiconductor substrate and the second semiconductor layer in the silicon-on-insulator region; and forming a buried insulating film inside the cavity.

This method decreases the difference in height between the surface of the second semiconductor layer in the bulk region and the surface of the second semiconductor layer in the SOI region. Therefore, elements are formed in the SOI region and in the bulk region with a smaller difference in height.

According to a third aspect of the invention, a semiconductor device includes: a silicon-on-insulator region and a bulk region both included in a same semiconductor substrate; a concave formed into an interior of the semiconductor substrate from a surface thereof in the silicon-on-insulator region; an insulating film formed within the concave; and a semiconductor layer formed on the insulating film; a surface of the semiconductor layer and the surface of the semiconductor substrate in the bulk region being at the same height.

This structure allows elements such as transistors on the semiconductor layer in the SOI region as well as on the semiconductor substrate in the bulk region to be formed in the same height.

### BRIEF DESCRIPTION OF THE DRAWINGS

The invention will be described with reference to the accompanying drawings, wherein like numbers reference like elements.

FIGS. 1A and 1B are drawings illustrating a method for manufacturing a semiconductor device according to an embodiment of the invention.

FIGS. 2A and 2B are drawings illustrating the method for manufacturing a semiconductor device according to an embodiment of the invention.

FIGS. 3A and 3B are drawings illustrating the method for manufacturing a semiconductor device according to an embodiment of the invention.

FIGS. 4A and 4B are drawings illustrating the method for manufacturing a semiconductor device according to an embodiment of the invention.

FIGS. 5A and 5B are drawings illustrating the method for manufacturing a semiconductor device according to an embodiment of the invention.

FIGS. 6A and 6B are drawings illustrating the method for manufacturing a semiconductor device according to an embodiment of the invention.

FIGS. 7A and 7B are drawings illustrating the method for manufacturing a semiconductor device according to an embodiment of the invention.

FIGS. 8A and 8B are drawings illustrating the method for manufacturing a semiconductor device according to an embodiment of the invention.

FIGS. 9A and 9B are drawings illustrating the method for manufacturing a semiconductor device according to an embodiment of the invention.

FIGS. 10A and 10B are drawings illustrating the method for manufacturing a semiconductor device according to an embodiment of the invention.

FIGS. 11A through 11D are drawings illustrating a method for manufacturing a semiconductor device according to an alternative embodiment of the invention.

### DESCRIPTION OF EXEMPLARY EMBODIMENTS

A semiconductor device and a manufacturing method thereof according to aspects of the invention will now be described with references to the accompanying drawings.

### First Embodiment

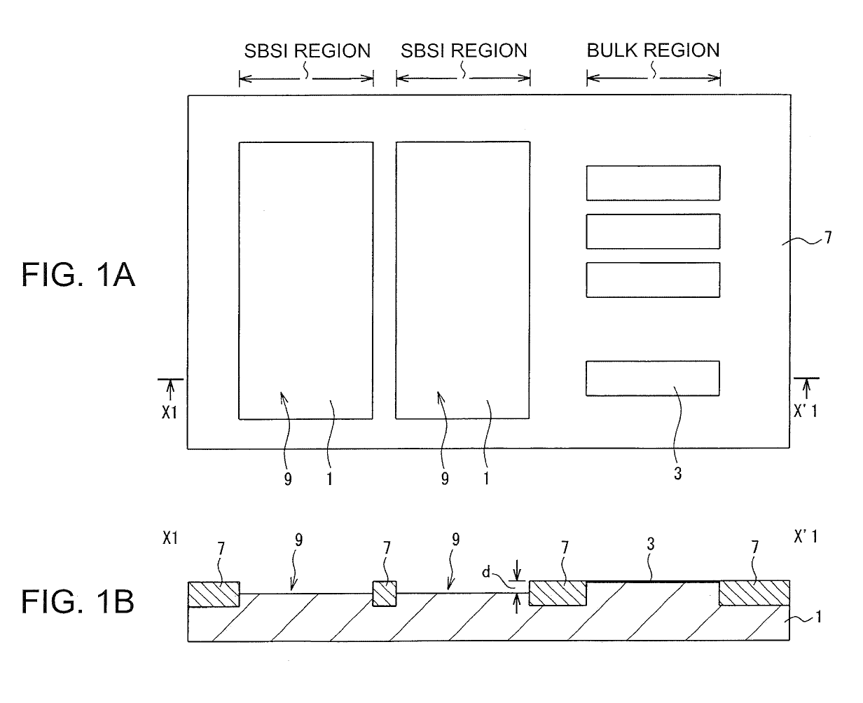

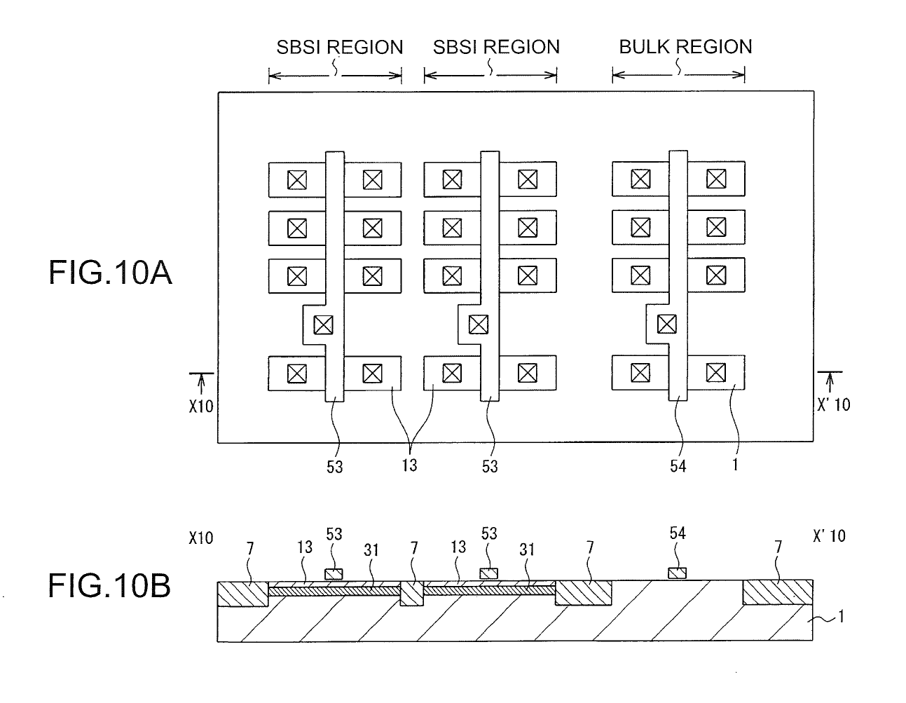

FIGS. 1A through 10B are drawings illustrating a method for manufacturing a semiconductor device according to a first embodiment, where FIGS. 1A through 10A are plan views illustrating the method, and FIGS. 1B through 10B are sectional views cutting FIGS. 1A through 10A along the lines X1-X′1 through X10-X′10 respectively. In FIG. 10A, the illustration of an insulating layer 33 is omitted in order to avoid complicating the drawing.

As shown in FIGS. 1A and 1B, a silicon (Si) substrate 1 is provided with an SBSI region and a bulk region, both regions may be provided in plural number. The rest of the region is an element isolation region (i.e. a region between the SBSI region and the bulk region; between one SBSI region and another, and between one bulk region and another). Here, the “SBSI region” according to this embodiment means a region in which the SBSI method is carried out, and this region includes SOI regions (regions in which SOI structures are formed) and regions in which trenches for removing SiGe are formed.

Referring now to FIGS. 1A and 1B, a recess LOCOS layer 7 is first formed on the Si substrate 1 in the element isolation region. Specifically, a silicon oxidation (SiO₂) film 3 and, subsequently thereon, an un-illustrated silicon nitride (SiN) film are formed on the entire top surface of the Si substrate 1. The SiO₂ film 3 is formed with a method such as thermal oxidation or CVD, and the SiN film is formed with a method such as CVD. Thereafter, the surface of the Si substrate 1 in the element isolation region is exposed by partially etching the SiN film and the SiO₂ film 3 with techniques of photolithography and etching. Subsequently, an un-illustrated concave is formed by etching the surface of the Si substrate 1 exposed from under the SiN film.

Thermal oxidation is then carried out on the Si substrate 1, thereby forming the recess LOCOS layer 7 in the Si substrate 1 within the element isolation region. Consequently, the recess LOCOS layer 7 is formed in the Si substrate 1 within the element isolation region. Since the recess LOCOS layer 7 is formed by oxidizing a bottom surface as well as a side surface of the concave formed within the Si substrate 1, the surface height of the recess LOCOS layer 7 is lower than that of the common LOCOS layer (in other words, a step between the recess LOCOS layer 7 and the Si substrate 1 is made smaller). Here, as shown in FIG. 1B, the recess LOCOS layer 7 is formed so that the height of the surfaces of the recess LOCOS layer 7 and of the Si substrate 1 in the bulk region becomes approximately the same.

Subsequently, the SiN film for oxidation prevention is removed from the SBSI region as well as from the bulk region by wet etching, using an etchant such as a hot phosphoric acid solution. Using a photolithography technique, an area over the Si substrate 1 in the bulk region is covered with an un-illustrated photoresist, and the SiO₂ film 3 in the SBSI region is removed in this state with etching which continues to etch the surface of the Si substrate 1 under the SiO₂ film 3, thereby forming a concave 9. The etching of the SiO₂ film 3 is carried out with one of dry etching and wet etching using an etchant such as buffered hydrofluoric acid (BHF), and the etching of the Si substrate 1 is carried out by, for instance, dry etching. In the dry etching process of forming the concave 9, the dry etching time is adjusted so that a depth d of the concave 9 measured from the surface of the Si substrate 1 becomes as large as the sum of film thicknesses of a SiGe layer and a Si layer which are to be formed in a subsequent process.

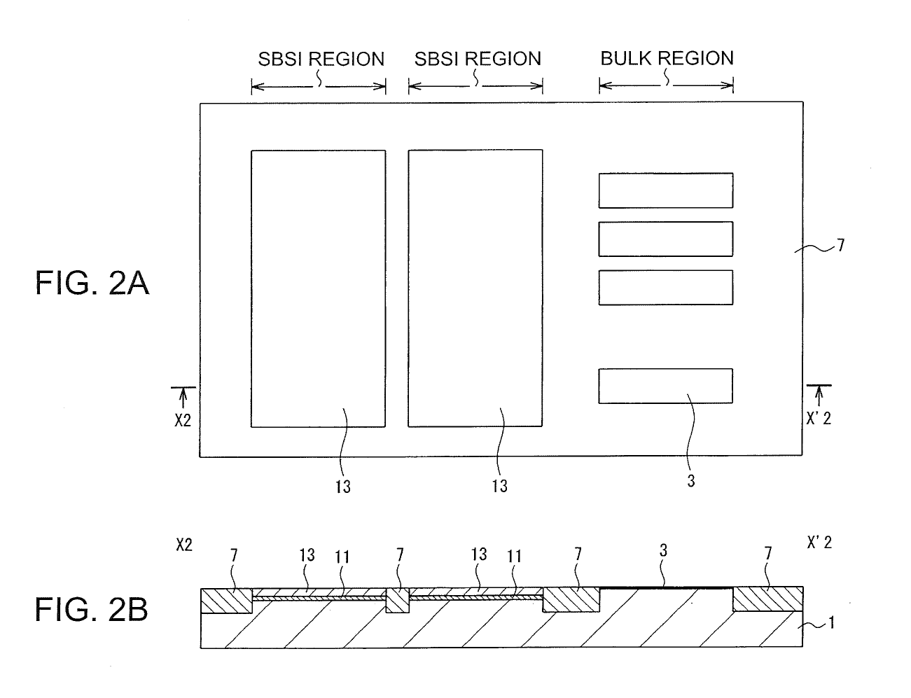

Referring now to FIGS. 2A and 2B, a silicon germanium (SiGe) layer 11 and a Si layer 13 are formed with a selective epitaxial growth, both layers having a single-crystalline structure, the SiGe layer 11 being formed on the surface of the Si substrate 1 in the SBSI region, and the Si layer 13 being formed on the SiGe layer 11. Examples of the thicknesses of the SiGe layer 11 and the Si layer 13 are 30 nm and 100 nm respectively. Here, since the surface of the Si substrate 1 in the bulk region is covered with the SiO₂ film 3, the forming of the SiGe layer 11 and the Si layer 13 in the bulk region is prevented. Moreover, as described above, the depth d of the concave 9 (refer to FIG. 1B) is as large as the sum of the film thicknesses of the SiGe layer 11 and the Si layer 13, making the surface of the Si layer 13 to have approximately the same height as that of the surface of the Si substrate 1.

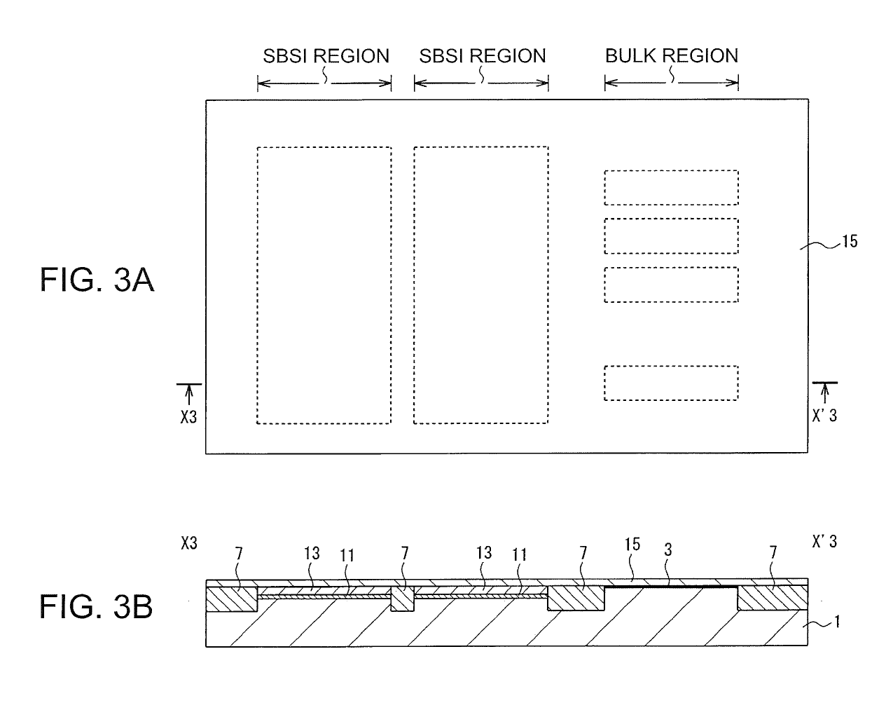

Subsequently, an un-illustrated thin SiO₂ film is formed on the entire surface over the Si substrate 1. This SiO₂ film is a film for protecting the surfaces of the Si layer 13 and the Si substrate 1 from the hot phosphoric acid solution during the removal of a SiN film 15 in a subsequent process. Refer to FIG. 3B for an example of the SiN film 15. The SiO₂ film for such surface protection may be formed with any one of thermo oxidation and CVD. In case of thermo oxidation, caution should be taken so that the processing temperature does not exceed the level in which no diffusion of Ge within SiGe occurs, for instance, 800° C.

Thereafter, the SiN film 15 is formed over the entire Si substrate 1 as shown in FIGS. 3A and 3B. This SiN film 15 functions as a support for supporting the Si layer 13, as well as a stopper layer against a CMP processing in a subsequent process. The SiN film 15 is formed, for instance, with CVD method. Here, the SiN film 15 is formed flat, since the surfaces of the recess LOCOS layer 7, the Si substrate 1 in the bulk region, and the Si layer 13 in the SBSI region are all leveled approximately to the same height.

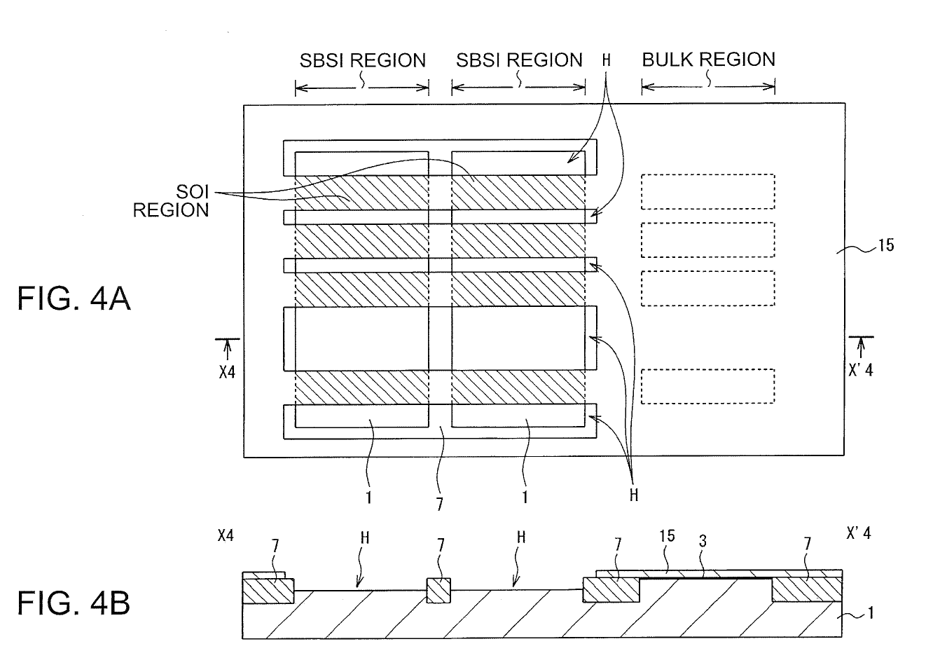

Subsequently, the SiN film 15 is partially etched by techniques of photolithography and etching. This process produces trenches H on the Si substrate 1, the trenches H exposing the side surfaces of SiGe layer 11 and the Si layer 13 in the SOI regions, as shown in FIGS. 4A and 4B. Here, the SOI region means an area in which the SOI structure is actually formed within the SBSI region. Referring to FIG. 4A, the SOI regions are illustrated as the areas indicated in oblique lines, i.e. covered with the SiN film 15 and sandwiched by the trenches H in plan view. In the etching process for forming the trenches H2, the etching of the SiGe layer 11 may either be stopped in the middle so that a portion thereof may be left on the Si substrate 1, or, be overetched so that a concave may be formed in the Si substrate 1.

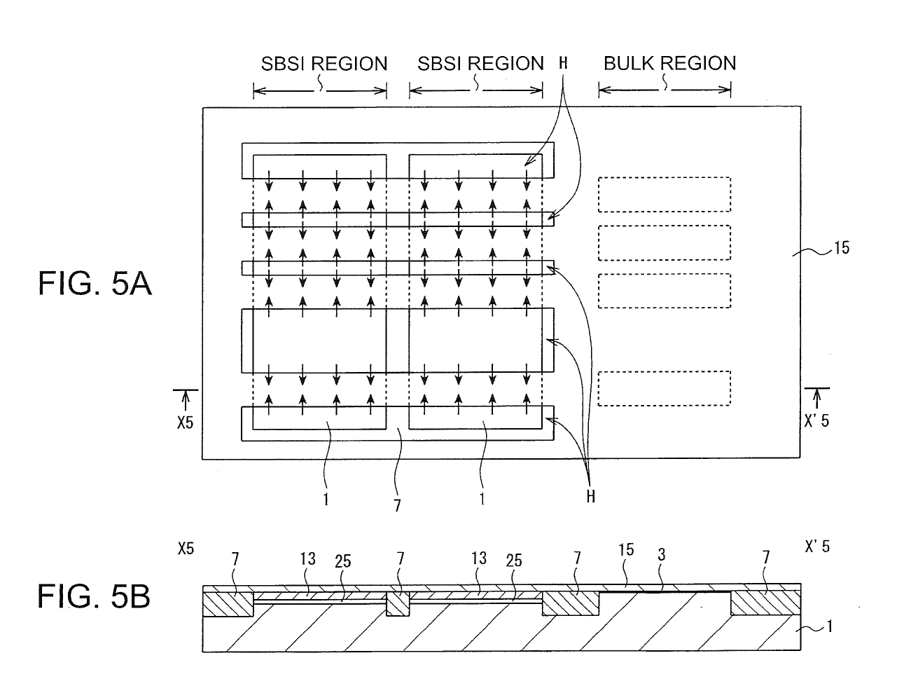

Referring now to FIG. 5A, an etchant such as a fluoro-nitric acid solution contacts each side surface of the Si layer 13 and the SiGe layer 11 through the trenches H, so as to selectively etch and remove the SiGe layer 11. Consequently, as shown in FIG. 5B, a cavity 25 is formed between the Si layer 13 and the Si substrate 1. In the wet etching using the fluoro-nitric acid solution, the etching ratio of SiGe is higher than that of Si (i.e. SiGe has a higher selection ratio compared to Si). Therefore, it is possible to etch and remove only the SiGe layer while leaving the Si substrate 1 and the Si layer 13. At one point during the formation of the cavity 25, the top surface of the Si layer 13 become supported by the SiN film 15.

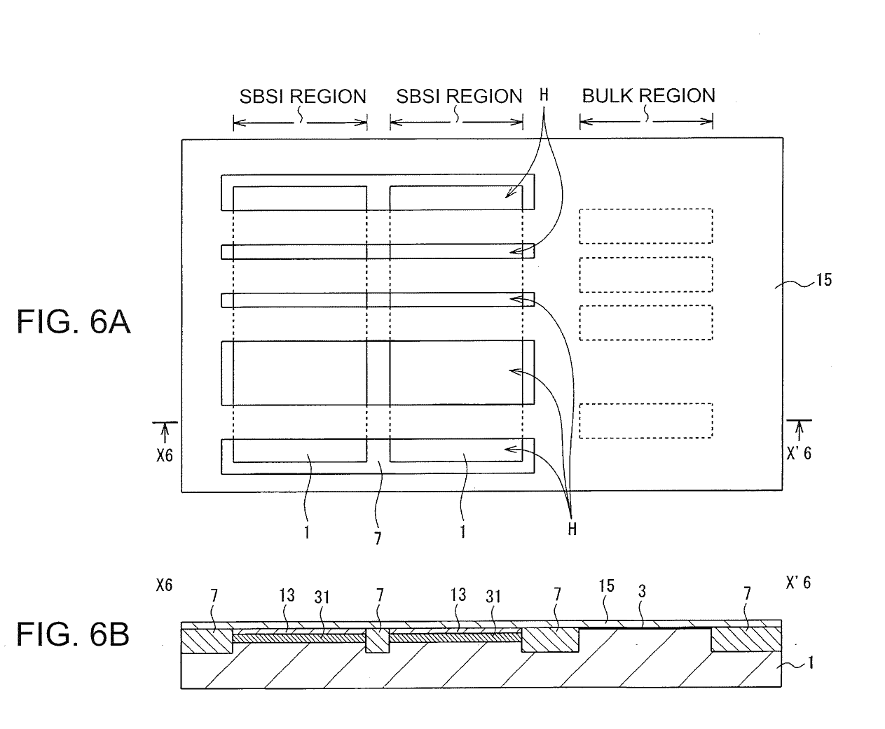

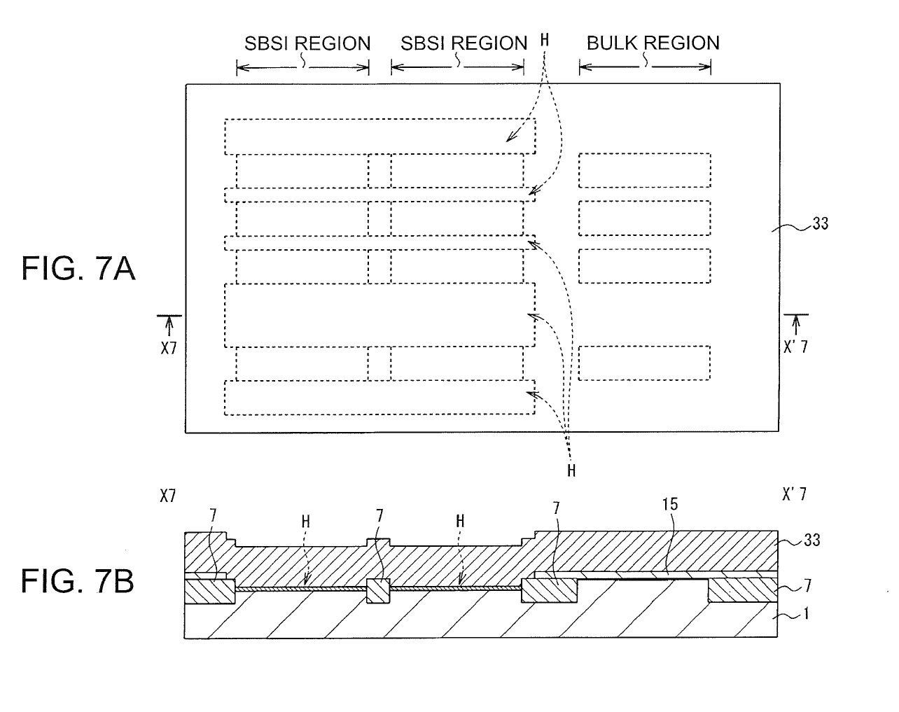

As shown in FIGS. 6A and 6B, the thermo oxidation of the Si substrate 1 and the Si layer 13 produces a SiO₂ film (i.e. a BOX layer) 31 inside the cavity 25. Thereafter, as shown in FIGS. 7A and 7B, the thick insulating layer 33 is formed on the entire surface over the Si substrate 1 with methods such as CVD, so as to bury the trenches H. The insulating layer 33 is, for instance, a SiO₂ film.

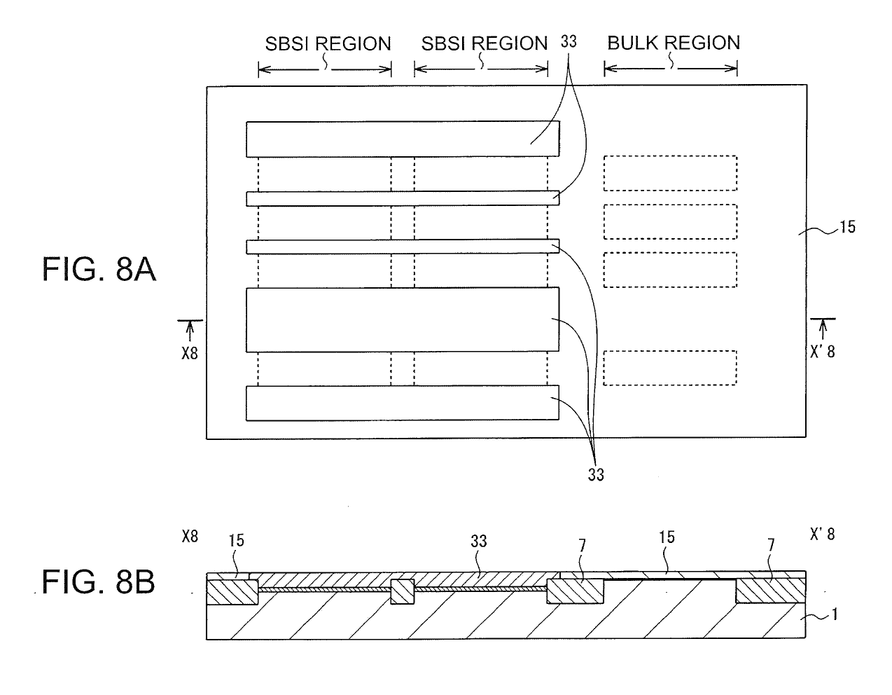

Referring now to FIGS. 8A and 8B, the surface of the insulating layer 33 is planarized by performing a CMP processing on the insulating layer 33. At this time, the SiN film 15 remaining in the regions excluding the trenches H functions as a stopper layer against the CMP. Moreover, since the heights of the surfaces of the recess LOCOS layer 7 and the Si substrate 1 in the bulk region are approximately the same, the SiN film 15 is formed flat in the regions including the element isolation region and the bulk region. This allows a polishing pad to be applied on the entire insulating layer 33 on the SiN film 15 in this CMP processing, thereby almost entirely removing the insulating layer 33 from the top of the SiN film 15. In other words, this is not the case in which the insulating layer 33 remains in a depression of the SiN film 15.

Subsequently, the SiN film 15 is removed from over the Si substrate 1 by wet etching, using an etchant such as a hot phosphoric acid solution. Here, since the surface of Si layer 13 (hereafter also referred to as “SOI layer 13”) and the surface of the Si substrate 1 in the bulk region are covered with the thin SiO₂ film, the surface oxidation of those surfaces caused by the hot phosphoric acid solution is prevented. The insulating layer 33 then undergoes wet etching, using an etchant such as BHF.

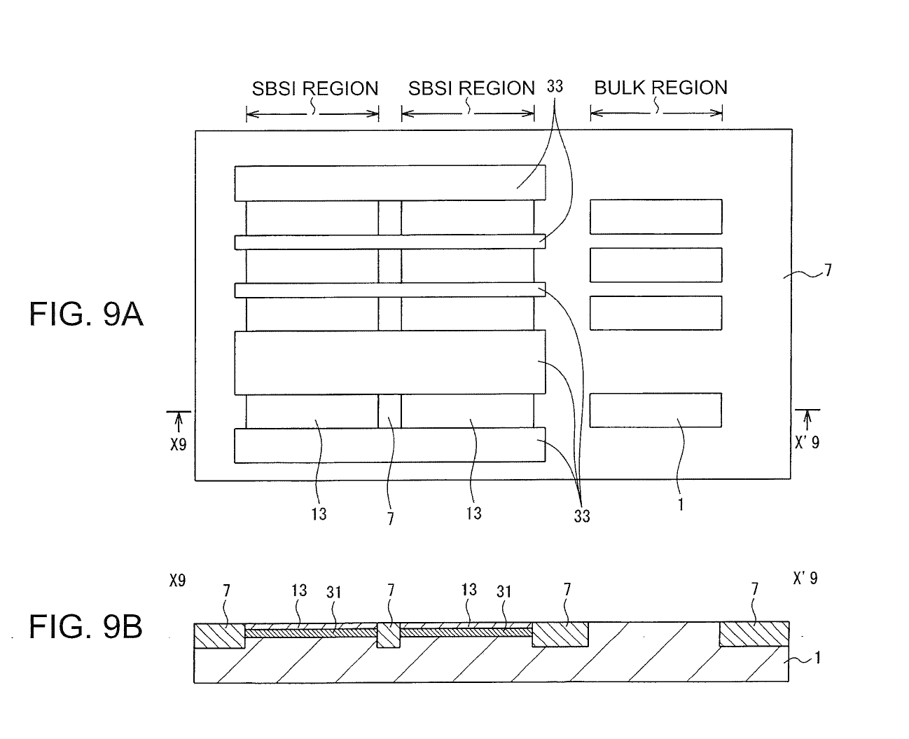

This exposes the surface of the Si layer 13 (i.e. SOI layer 13) in the SBSI region, as shown in FIGS. 9A and 9B. In the bulk region, layers such as the SiO₂ film 3 (refer to FIG. 1B for an example thereof is etched, and the surface of the Si substrate 1 is exposed. The BOX layer 31 is arranged under the SOI layer 13 as shown in FIGS. 9A and 9B, and the recess LOCOS layer 7 and the insulating layer 33 are arranged in the periphery of the SOI layer 13, making the SOI layer 13 electrically isolated from the Si substrate 1 (in other words, a floating state).

Thereafter, MOS transistors are formed on the SOI layer 13 and on the Si substrate 1 in the bulk region, by using, for instance, the common CMOS process. Ion implantation for Vth adjustment may be optionally carried out on the surfaces of the Si substrate 1 in the bulk region as well as on the SOI layer 13, if necessary. Subsequently, those surfaces are thermally oxidized so as to form un-illustrated gate oxidation films in the SOI region and in the bulk region. A film such as polysilicon is then formed over the Si substrate 1 in the bulk region and over the SOI layer 13 with methods such as CVD, and thereafter is patterned with techniques such as photolithography and dry etching. Consequently, gate electrodes 53 are formed over the SOI layer 13, having the gate oxidation film therebetween. At the same time, a gate electrode 54 is formed over the Si substrate 1, having the gate oxidation film therebetween.

At this time, the gate electrodes 53 and 54 are formed approximately at the same height, since the surfaces of the SOI layer 13 and the Si substrate 1 in the bulk region are aligned approximately to the same height. After forming the gate electrodes 53 and 54, an ion implantation of dopants such as As, P, and B is carried out into the SOI layer 13 as well as into the Si substrate 1 in the bulk region, using those gate electrodes 53 and 54 as a mask. Further, a heat treatment is carried out so as to activate those dopants, thereby forming un-illustrated source electrodes and drain electrodes on both sides of the gate electrodes 53 and 54.

As described, according to the first embodiment of the invention, the surfaces of the Si substrate 1 in the bulk region and the SOI layer 13 are aligned to the same height, so that the gate electrodes 53 and 54 are formed approximately at the same height. This allows a focal depth of the SOI region to approximately match that of the bulk region in the photolithography process for forming the gate electrodes 53 and 54, thereby enabling a simultaneous focusing on both the SOI region and the bulk region. Therefore, compared to the case of individually focusing on the SOI region and on the bulk region so as to carry out the exposure process, the above method reduces the complexity of focusing, thereby shortening the processing time and the like in the exposure process. Consequently, it is possible to provide a method for manufacturing a semiconductor device with high production efficiency.

Moreover, the simultaneous focusing on both the SOI region and the bulk region allows the exposure processing thereof to be carried out at the same time, thereby allowing the formation of the gate electrodes 53 and 54 in a high precision. Consequently, a semiconductor device is fabricated in accordance with the designed values, and therefore the semiconductor device exhibits desired performance and is highly reliable.

### Second Embodiment

In the first embodiment, the difference in height between the surface of the Si layer 13 and the surface of the Si substrate 1 in the bulk region is reduced, by forming the concave 9 inside the Si substrate 1 in the SBSI region and thereafter causing selective epitaxial growth of the SiGe layer 11 and the Si layer 13 inside the concave 9. Particularly, if the depth d of the concave 9 equals the sum of the film thicknesses of the SiGe layer 11 and the Si layer 13, a difference in height between the surface of the Si layer 13 in the SOI region and the surface of the Si substrate 1 in the bulk region becomes approximately zero (0).

The method for reducing the difference in height between those surfaces is not limited thereto. For instance, instead of forming a concave by etching the Si substrate 1 in the SBSI region, the aforementioned difference in height may in effect be reduced by causing epitaxial growth of a Si layer on a Si substrate in a bulk region. If the Si layer is directly grown on the surface of the Si substrate with epitaxy, the Si layer practically becomes the substrate surface. The second embodiment describes this option.

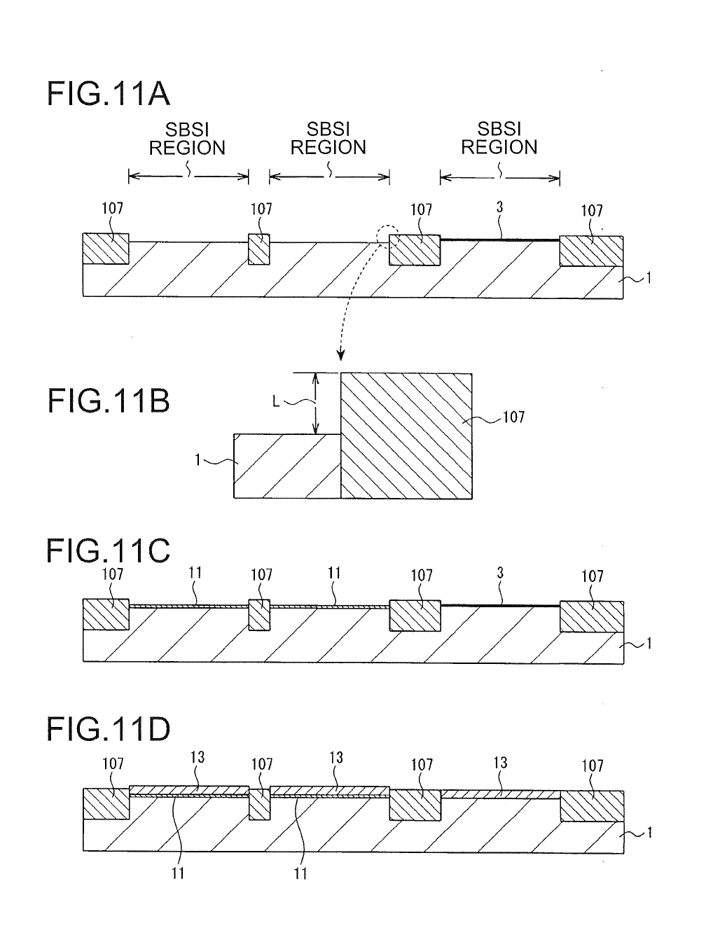

FIGS. 11A to 11D are sectional drawings illustrating a method for manufacturing a semiconductor device according to the second embodiment. The same signs and numerals as that of FIGS. 1A to 10B described in the first embodiment are used in FIGS. 11A to 11D for the parts having the same structures and properties as that of the first embodiment, and the detailed description thereof is omitted. In FIG. 11A, the recess LOCOS layer 107 is first formed on the Si substrate 1 in the element isolation region. The method for forming the recess LOCOS layer 107 is similar to that of the first embodiment. However, as shown in FIG. 11B, the recess LOCOS layer 107 is formed so that the surface thereof is higher than the surface of the Si substrate 1, and, the step L between the surfaces becomes approximately as high as the thickness of the Si layer 13 which is to be formed in the subsequent process.

The height of the surface of the recess LOCOS layer 107 varies depending on parameters such as the processing temperature of thermal oxidation, processing time, and a type of gas being used. It also varies depending on the depth of the concave in the element isolation region formed prior to the thermal oxidation of the recess LOCOS layer 107. That is to say, under the same thermal oxidation condition, if the depth of the concave is shallow, the surface position of the recess LOCOS layer becomes higher; and if the depth of the concave is deep, the surface position of the recess LOCOS layer becomes lower. The depth of the concave is adjustable by changing the duration of the dry etching.

Consequently, by adjusting at least one parameter of the aforementioned thermal oxidation, and/or, by adjusting the dry etching time for forming the concave, the recess LOCOS layer 107 can be formed in the structure described above. In other words, the surface thereof is positioned higher than the surface of the Si substrate 1, and, the step L between the surfaces becomes approximately as high as the thickness of the Si layer 13 which is to be formed in the subsequent process. In the second embodiment, the recess LOCOS layer 107 is formed in this structure by, for instance, setting the dry etching time to be relatively short for forming a shallow concave.

Subsequently, the SiN film for oxidation prevention is removed from the SBSI region as well as from the bulk region by wet etching, using an etchant such as a hot phosphoric acid solution. The SiO₂ film 3 in the SBSI region is removed from the top of the Si substrate 1 by photolithography and etching techniques. The etching of the SiO₂ film 3 includes either a dry etching or a wet etching which uses an etchant such as BHF.

Thereafter, as shown in FIG. 11C, a silicon germanium (SiGe) layer 11 having a single-crystalline structure is selectively grown on the Si substrate 1 in the SBSI region with epitaxy. At this time, since the surface of the Si substrate 1 in the bulk region is covered with the SiO₂ film 3, the forming of the SiGe layer 11 thereon is prevented. The SiO₂ film 3 then undergoes wet etching using an etchant such as BHF, so that the surface of the Si substrate 1 within the bulk region is exposed. Thereafter, as shown in FIG. 11D, the Si layer 13 having a single-crystalline structure is selectively grown with epitaxy on the surface of the SiGe layer 11 in the SBSI region as well as on the Si substrate 1 in the bulk region.

At this time, the step L (refer to FIG. 11B) between the surface of the recess LOCOS layer 107 and surface of the Si substrate 1 has approximately the same size as the thickness of the Si layer 13. Consequently, as shown in FIG. 11D, when the Si layer 13 is formed, the surface of the recess LOCOS layer 107 and the surface of the Si layer 13 in the bulk region are aligned approximately to the same height. That is to say, the surface of the Si layer 13 in the SBSI region, the surface of the Si layer 13 in the bulk region, and the surface of the recess LOCOS layer 107 are aligned to approximately the same height. Strictly saying, the surface of the Si layer 13 in the SBSI region exists at a position higher, by the amount equivalent to the thickness of the SiGe layer 11, than the surface of the Si layer 13 in the bulk region. The thickness of the SiGe layer 11 is, for instance, approximately 30 nm.

The rest of the processes are the same as that of the first embodiment. Specifically, the SiGe layer 11 is removed, and a cavity is formed between the Si substrate 1 in the bulk region and the Si layer 13. A BOX layer is then formed inside this cavity. Thereafter, elements such as MOS transistors are formed on the Si layer (SOI layer) 13 and on the surface of Si substrate 1 in the bulk region.

As described, according to the second embodiment, the difference in height between the surface of the Si layer 13 and the surface of the Si substrate 1 in the bulk region is substantially reduced to close to zero, and the gate electrodes 53 and 54 are formed to have an approximately the same height, thereby obtaining a similar effect as that of the first embodiment.

In the first and the second embodiments, the Si substrate 1, the SiGe layer 11, and the Si layer (SOI layer) 13 respectively correspond to the ‘semiconductor substrate’, the ‘first semiconductor layer’, and either the ‘second semiconductor layer’ or the ‘semiconductor layer’ in the aforementioned aspects of the invention. Moreover, the SiO₂ film 3 and the concave 9 respectively correspond to the “protection film” and the “concave” in the aforementioned aspects of the invention. Still further, the BOX layer 31 corresponds to one of the ‘buried insulating film’ and ‘insulating film’ in the aforementioned aspects of the invention.

What is claimed is:

1. A method for manufacturing a semiconductor device having a silicon-on-insulator region and a bulk region in a same semiconductor substrate, the method comprising:
(a) etching the semiconductor substrate in the silicon-on-insulator region so as to form a concave;
(b) forming a first semiconductor layer and subsequently a second semiconductor layer on the semiconductor substrate in the silicon-on-insulator region, so as to bury the concave;
(c) etching the second semiconductor layer and the first semiconductor layer partially, so as to form a trench which exposes a side surface of the first semiconductor substrate in the silicon-on-insulator region;
(d) etching the first semiconductor layer through the trench with an etching condition in which the first semiconductor layer is easier to be etched than the second semiconductor layer, so as to form a cavity between the semiconductor substrate and the second semiconductor layer in the silicon-on-insulator region; and
(e) forming a buried insulating film inside the cavity.

2. The method for manufacturing a semiconductor device according to claim 1, wherein the semiconductor substrate is etched in the step (a) so that the depth of the concave becomes as large as a sum of film thicknesses of the first semiconductor layer and the second semiconductor layer.

3. The method for manufacturing a semiconductor device according to claim 1, further comprising:
(f) forming a protection film on the semiconductor substrate in the bulk region, prior to the step (b); and
(g) exposing a surface of the semiconductor substrate in the silicon-on-insulator region from under the protection film;
the step (b) including selective epitaxial growth of the first semiconductor layer on the surface of the semiconductor substrate exposed from under the protection film, as well as the selective epitaxial growth of the second semiconductor layer on the surface of the first semiconductor layer.

4. The method for manufacturing a semiconductor device according to claim 1, further comprising;
(h) forming a support from over the second semiconductor layer in the silicon-on-insulator region to over the semiconductor substrate in a vicinity of the silicon-on-insulator region, between the forming of the second semiconductor layer in the step (b) and the step (d);
the step (d) including etching the first semiconductor layer under the second semiconductor layer, in a state the semiconductor layer in the silicon-on-insulator region being supported by the support.

5. The method for manufacturing a semiconductor device according to claim 4, further comprising;
forming a recess local-oxidation-of-silicon layer on the semiconductor substrate in the vicinity of the silicon-on-insulator region as an element isolation layer, prior to the step (a);
the step (h) including forming the support from over the semiconductor layer in the silicon-on-insulator region to over the recess local-oxidation-of-silicon layer.

6. A method for manufacturing a semiconductor device having a silicon-on-insulator region and a bulk region in a same semiconductor substrate, the method comprising:
forming a first semiconductor layer on the semiconductor substrate in the silicon-on-insulator region, while not forming the first semiconductor layer on the semiconductor substrate in the bulk region;
forming a second semiconductor layer on the first semiconductor layer in the silicon-on-insulator region as well as on the semiconductor substrate in the bulk region;
etching the second semiconductor layer and the first semiconductor layer partially, so as to form a trench which exposes a side surface of the first semiconductor substrate in the silicon-on-insulator region;
etching the first semiconductor layer through the trench with an etching condition in which the first semiconductor layer is easier to be etched than the second semiconductor layer, so as to form a cavity between the semiconductor substrate and the second semiconductor layer in the silicon-on-insulator region; and
forming a buried insulating film inside the cavity.

7. A semiconductor device, comprising:
a silicon-on-insulator region and a bulk region both included in a same semiconductor substrate;
a concave formed into an interior of the semiconductor substrate from a surface thereof in the silicon-on-insulator region;
an insulating film formed within the concave; and
a semiconductor layer formed on the insulating film;
a surface of the semiconductor layer and the surface of the semiconductor substrate in the bulk region being at the same height.
